(19) United States
(12) Patent Application Publication
(10) Pub. No.: US 2010/0037826 A1
(43) Pub. Date: Feb. 18, 2010

(54) VACUUM VAPOR PROCESSING APPARATUS

(76) Inventors: Hiroshi Nagata, Ibaraki (JP); Yoshinori Shingaki, Ibaraki (JP)

Correspondence Address: CERMAK KENEALY VAIDYA & NAKAJIMA LLP, 515 EAST BRADDOCK RD SUITE B, Alexandria, VA, 22314, US

(21) Appl. No.: 12/440,733

(22) PCT Filed: Sep. 10, 2007
(86) PCT No.: PCT/JP2007/067571

§ 371 Date: May 19, 2009

(30) Foreign Application Priority Data
Sep. 14, 2006 (JP) 2006-248963

(51) Int. Cl. C23C 14/24; H01F 41/02

(52) U.S. Cl. 118/725

(57) ABSTRACT

There is provided a vacuum vapor processing apparatus which is capable of adjusting the amount of supply of metal atoms to an object to be processed and which has a simple construction. The vacuum vapor processing apparatus is provided with: a vacuum chamber (12) capable of keeping inside thereof at a predetermined pressure; a processing vessel (2) and an evaporating vessel (3), both being disposed in the vacuum chamber at a distance from, and in communication with, each other; and heating means (6a, 6b) capable of heating the processing vessel and the evaporating vessel in a state in which the object to be processed is disposed in the processing vessel (S) and in which metal evaporating material (V) is disposed in the evaporating vessel. The processing vessel and the evaporating vessel are respectively heated by the heating means to thereby evaporate the metal evaporating material while raising the object to be processed to a predetermined temperature so that evaporated metal atoms are supplied to the surface of the object to be processed in the processing vessel.

### FIELD OF THE INVENTION

The present invention relates to a vacuum vapor processing apparatus suitable for performing a processing (vacuum vapor processing): in which an object to be processed is heated inside a processing chamber, and also metal evaporating material is evaporated in an evaporation chamber, and the evaporated metal atoms are caused to be adhered to, and deposited on, a surface of the object to be processed of a predetermined temperature to thereby form a metallic film and, further; in which, in case the object to be processed has a crystal structure, the metal atoms are caused to be diffused into the grain boundaries at the same time as the adhesion thereof to the surface of the object to be processed.

### BACKGROUND ART

This kind of vacuum vapor processing apparatus is used to improve the magnetic properties of, e.g., a Nd—Fe—B (or a Nd—Fe—B system) sintered magnet, and there is known one which is constituted by a hermetically sealed vessel made up of glass tube, and an electric furnace. In this vacuum vapor processing apparatus, an object to be processed which is the Nd—Fe—B sintered magnet and a metal evaporating material which is rare earth metal selected from the group consisting of Yb, Eu, Sm are contained, in a mixed state, inside the hermetically sealed vessel. The pressure inside the vessel is reduced to a predetermined pressure by means of a vacuum pump or the like and sealed. Thereafter, the above materials are contained inside the electric furnace and are heated (e.g., to 500° C.) while this hermetically sealed vessel is rotated.

Once the hermetically sealed vessel is heated, the metal evaporates to thereby form a metal vapor atmosphere inside the hermetically sealed vessel. The metal atoms in the metal vapor atmosphere get adhered to the sintered magnet that has been heated to substantially the same temperature. In addition, as a result of diffusion of the adhered metal atoms into the grain boundary phases of the sintered magnet, the metal atoms are homogeneously introduced in a desired amount into the surface of the sintered magnet and the grain boundary phases, whereby magnetization and coercive force are improved or recovered (patent document 1 and patent document 2).
Patent document 1: JP-A-2002-105503 (see, e.g., FIG. 1 and FIG. 2)
Patent document 2: JP-A-2004-296973 (see, e.g., claims)

### DISCLOSURE OF THE INVENTION

### Problems to be Solved by the Invention

By the way as described above, in case the processing is performed in which, in order to improve the magnetic properties of the sintered magnet, the metal atoms are adhered to the surface of the sintered magnet as the object to be processed and also are diffused into the grain boundaries, the temperature to heat the hermetically sealed vessel by controlling the electric furnace is determined by the heating temperature of the sintered magnet that is the object to be processed. In the above-described apparatus, since the metal evaporating material and the object to be processed are disposed in a state of being mixed with each other, the metal evaporating material is also heated to substantially the same temperature. Therefore, the amount of supply of the metal atoms in the metal vapor atmosphere to the object to be processed is determined by the vapor pressure at the temperature in question. Therefore, there is a problem in that the amount of supply of the metal atoms in the metal vapor atmosphere to the object to be processed cannot be controlled.

In addition, in order to introduce the metal atoms in a desired amount into substantially the entire surface of the sintered magnet, there is required a driving mechanism for rotating the hermetically sealed vessel. As a result, the apparatus construction becomes complicated and the cost becomes high. Still furthermore, since the metal evaporating material and the object to be processed are disposed in a state of being mixed together, there is a disadvantage in that the metal evaporating material that has been melted directly gets adhered to the object to be processed.

Therefore, in view of the above points, the object of this invention is to provide a vacuum vapor processing apparatus in which the amount of evaporated metal atoms to an object to be processed can be adjusted, and in which the structure thereof is simple.

### Means for Solving the Problems

In order to solve the above problems, the vacuum vapor processing apparatus according to the invention comprises: a vacuum chamber capable of keeping inside thereof at a predetermined pressure; a processing vessel and an evaporating vessel, both being disposed in the vacuum chamber at a distance from, and in communication with, each other; and a heating means capable of heating the processing vessel and the evaporating vessel in a state in which an object to be processed is disposed in the processing vessel and in which metal evaporating material is disposed in the evaporating vessel. The processing vessel and the evaporating vessel are respectively heated by the heating means to thereby evaporate the metal evaporating material while raising the object to be processed to a predetermined temperature so that evaporated metal atoms are supplied to a surface of the object to be processed in the processing vessel.

According to the invention, the object to be processed is set in position in the processing vessel and the metal evaporating material is set in position in the evaporating vessel, respectively. The heating means is operated at a reduced pressure in the vacuum chamber to thereby heat the processing vessel and the evaporating vessel, respectively. When the metal evaporating material reaches a predetermined temperature at a certain pressure, the metal evaporating material starts evaporation. In this case, since the object to be processed and the metal evaporating material are contained in separate vessels, even in case the object to be processed is sintered magnet and the metal evaporating material is rare earth metal, there is no possibility that the melted rare earth metal directly adheres to the sintered magnet whose Nd-rich phase on the surface thereof is melted.

Then, the metal atoms evaporated in the evaporating vessel are supplied to the processing vessel and move toward the object to be processed directly or by repeating collisions inside the processing vessel in a plurality of directions, thereby adhering to, and depositing on, the object to be processed. In case the object to be processed has a crystalline structure, the metal atoms adhered to the surface of the object to be processed that has been heated to the predetermined temperature are diffused into the grain boundaries. At that time, since the vessels are separated into the processing vessel in which the object to be processed is disposed and the evaporating vessel in which the metal evaporating material is disposed, it becomes possible to independently heat the object to be processed and the metal evaporating material. Irrespective of the heating temperature of the object to be processed, the evaporating vessel can be heated to an arbitrary temperature to change the vapor pressure in the evaporating vessel, whereby the amount of supplying the evaporated metal atoms to the object to be processed can be adjusted.

If the evaporating vessel is provided with a pan which is capable of disposing therein the metal evaporating material, the amount of supply of the evaporated metal atoms to the object to be processed can further be adjusted to advantage.

Further, if an adjusting plate that adjusts an amount of supply of the evaporated metal atoms to the processing vessel is mounted on an open upper surface of the pan or in a communicating passage between the processing vessel and the evaporating vessel, the amount of supply of the evaporated metal evaporating material is determined: in case the adjusting plate is not mounted, on the opening area on the upper surface of the pan and; in case the adjusting plate is mounted, such that the amount of metal atoms to reach the processing chamber through this adjusting plate decreases, whereby the amount of supply of the metal evaporating material to the object to be processed can be adjusted. In this case, the area of opening on the upper surface of the pan may be increased or decreased to thereby increase or decrease the amount of evaporation of the metal evaporating material at a certain temperature. In addition, the sectional area of the communicating passage between the processing vessel and the evaporating vessel may be varied to thereby increase or decrease the amount of metal atoms to reach the processing vessel through this communicating passage.

Preferably, the processing vessel is a first box body comprising a box part whose upper surface is open, and a lid part which is detachably mounted on the open upper surface of the box part. The first box part can be taken into, or taken out of, the vacuum chamber, and the inner space of the first box part is reduced to a predetermined pressure accompanied by pressure reduction in the vacuum chamber. According to this arrangement, there is no need of a separate evacuating means for use in pressure reduction of the processing vessel, resulting in a cost reduction. Further, after, e.g., having stopped the evaporation of the metal evaporating material, the processing vessel can be further reduced in pressure inside thereof without taking out the processing vessel. In addition, by arranging so that the processing vessel containing therein the object to be processed can be taken into, or taken out of, the vacuum chamber, there is no need of providing in the vacuum chamber a mechanism, and the like for taking into, or taking out of, the box body the object to be processed, resulting in a simpler construction of the apparatus itself. In this case, if an arrangement is made such that a plurality of box bodies are contained inside the vacuum chamber to enable simultaneous processing, it can cope with mass production.

In this case, if an arrangement is made that a bearing grid is provided which is capable of mounting thereon the object to be processed at a predetermined height from a bottom of the processing vessel, and that the bearing grid is made by arranging a plurality of wire rods, e.g., the metal atoms evaporated in the evaporating vessel are supplied to substantially the entire surface of the object to be processed either directly or from a plurality of directions by repeating collisions. Therefore, there is no need of a rotating mechanism and the like for rotating the object to be processed. The construction of the apparatus can thus be advantageously simplified.

On the other hand, preferably the evaporating vessel is a second box body comprising a box part whose upper surface is open, and a lid part which is detachably mounted on the open upper surface of the box part. The second box part can be taken into, or taken out of, the vacuum chamber, and the inner space of the second box part is reduced to a predetermined pressure accompanied by pressure reduction in the vacuum chamber.

By arranging such that the processing vessel, the evaporating vessel, and the heating means: are made of a material that is free from reaction with the metal evaporating material; or have, on at least the surface thereof, a lining film made of a material that is free from reaction with the metal evaporating material, the other metal atoms can advantageously be prevented from entering into the metal vapor atmosphere. Further, the recovery of the metal evaporating material becomes easy. This is particularly effective in case Dy and Tb, that are scanty as natural resources and stable supply thereof cannot be expected, are contained in the metal evaporating material.

In case the object to be processed is an iron-boron-rare earth sintered magnet, and the metal evaporating material contains at least one of Dy and Tb, the amount of supply of the evaporated Dy and Tb to the sintered magnet is adjusted so that the metal atoms can be adhered to the surface of the sintered magnet. The adhered metal atoms can advantageously be diffused into the grain boundary phases of the sintered magnet before a thin film of Dy, Tb is formed on the surface of the sintered magnet.

### EFFECT OF THE INVENTION

As described hereinabove, the vacuum vapor processing apparatus of the invention has an effect in that it has a simple construction and that the amount of supply of the evaporated metal atoms to the object to be processed can be adjusted.

### BEST MODE FOR CARRYING OUT THE INVENTION

With reference to FIGS. 1 and 2, reference numeral 1 denotes a vacuum vapor processing apparatus 1 of this invention. The vacuum vapor processing apparatus 1 has a vacuum chamber 12 that can be reduced to a predetermined pressure (e.g., 1×10⁻⁵ Pa) and held in that state through vacuum exhaust means 11 such as a turbo-molecular pump, cryo-pump, diffuser pump, and the like. In the vacuum chamber 12 a processing vessel 2 and an evaporating vessel 3 are disposed in a vertical direction with each other. The processing vessel 2 and the evaporating vessel 3 are communicated to each other through a communicating passage 4. An object to be processed S and metal evaporating material V which are to be appropriately selected depending on the desired processing are respectively disposed in the processing vessel 2 and the evaporating vessel 3. The metal atoms evaporated in the evaporating vessel 3 can be supplied to the object to be processed inside the processing vessel 2 through the communicating passage 4.

The processing vessel 2 is a first box body made up of a box part 21 which is a rectangular parallelepiped with an upper surface left open, and a lid part 22 which is capable of being attached to, and detached from, the upper surface of the first box part 21. The processing vessel 2 can be taken into, and out of, the vacuum chamber 12. On an outer periphery of the lid part 22, a flange 22a which is bent downward is formed over the entire circumference. When the lid part 22 is mounted on the upper surface of the box part 21, the flange 22a is fit into the outer wall of the box part 21 (in this case, vacuum sealing such as a metal seal is not provided) to thereby define a processing chamber 20 which is isolated from the vacuum chamber 12. When the vacuum chamber 12 is reduced to a predetermined pressure (e.g., 1×10⁻⁵ Pa) via evacuating means 11, the processing chamber 20 is reduced to a pressure that is higher approximately by half a digit (e.g., 5×10⁻⁴ Pa).

The volume of the processing chamber 20 is set, taking into consideration a mean free path of metal evaporating material V, so that the evaporated metal atoms can be supplied to the object to be processed S directly or in a plurality of directions after repeating collisions. The wall thicknesses of the box part 21 and the lid part 22 are set so that they are not deformed by heat when they are heated by a heating means described below.

Inside the processing chamber 20 there is formed a bearing grid 21a made by disposing in lattice form a plurality of wire rods (e.g., 0.1 mm˜10 mm φ) at a predetermined height from the bottom surface. A plurality of objects S to be processed can be placed on this baring grid 21a. According to this arrangement, the metal atoms evaporated inside the evaporating vessel 3 positioned below the processing vessel 2 are supplied through the communicating passage 4 to substantially the entire surface of the object to be processed either directly or from a plurality of directions by repeating collisions. Therefore, there is no need of rotating the box body 2 itself or the object S to be processed inside the box body 2.

On the other hand, the evaporating vessel 3 is a second box body formed into a rectangular parallelepiped. The second box body 3 can be taken into, or taken out of, the vacuum chamber 2 and defines an evaporating chamber 30 that is isolated from the vacuum chamber 12. On an upper surface of the second box body 3, there is provided a circular opening 31. The cylindrical communicating passage 4 which is in communication with the evaporating chamber 30 is integrally provided so as to extend upward while enclosing the opening 31. A circular opening 2a is provided on the bottom surface of the first box body 2. When each of the first and second box bodies 2, 3 is disposed in a predetermined position inside the vacuum chamber 12, the upper surface of the communicating passage 4 comes into surface contact with the lower surface of the box body 2 and, also, the opening 2a coincides with the opening upper end of the communicating passage 4, thereby bringing the processing chamber 20 and the evaporating chamber 30 into communication with each other. In other words, there is defined a space that communicates the processing chamber 20 with the evacuating chamber 30 through the communicating passage 4 and that is isolated from the vacuum chamber 12. According to this arrangement, the evaporating chamber 30 is evacuated through the processing chamber 20 when the vacuum chamber 12 is reduced in pressure via the evacuating means 11. The processing chamber 20 and the evaporating chamber 30 are thus reduced to a pressure that is higher than that of the vacuum chamber 12 by half a digit.

Further, the evaporating chamber 30 is provided with a pan 51 which is of recessed shape in cross-section, so that metal evaporating material V in granular form or bulk form can be held therein. On an open upper surface of the pan 51 there is detachably placed a lid body 52 which is provided over the entire surface thereof with a plurality of holes 52a of the same diameter. This lid body 52 serves the purpose of an adjusting plate which adjusts the amount of supply of the evaporated metal atoms to the processing chamber 20 through the communicating passage 4. According to this arrangement, when the lid body 52 is not placed in position, the amount of evaporation of the metal evaporating material is determined depending on the area of opening on the upper surface of the pan 51. When the lid body 52 is placed in position, the amount of metal atoms to reach the processing chamber 20 through the lid body 52 is reduced, whereby the amount of supply of the metal evaporating material V to the object S to be processed can be adjusted. In this case, an arrangement may also be made such that, by increasing or decreasing the area of the opening in the upper surface of the pan 51, the amount of evaporation may be increased or decreased at a uniform temperature. Further, by changing the total opening area of the holes 52a relative to the surface are of the lid body 52, the amount of metal atoms to reach the processing chamber 20 through the lid body 52 may also be increased or decreased.

When the metal evaporating material V is Dy and Tb, if the first and second box bodies 2, 3 of Al₂O₃ make that are ordinarily used in a vacuum apparatus in general are employed, there is a possibility that the evaporated Dy and Tb react with Al₂O₃ to thereby form products of reaction on the surface of the box bodies, and atoms of Al enter into the metal vapor atmosphere. Accordingly each of the first and second box bodies 2, 3, the communicating passage 4 and the pan 51 (inclusive of the lid body 52) are made, e.g., of Mo, W, V, Ta or alloys thereof (inclusive of rare earth elements added Mo alloy, Ti added Mo alloy and the like), CaO, Y₂O₃ or oxides of rare earth elements, or constituted by the construction in which these materials are formed into a film as an inner lining on the surface of the other thermal insulation material. According to this arrangement, the other metal atoms can be prevented from entering into the metal vapor atmosphere and, in addition, it becomes easy to recover the metal evaporating material V adhered to the surfaces, e.g., of the box bodies 2, 3. The wire-rod material to constitute the bearing grid 21a inside the first box body 2 is also made of a material that does not react with the metal evaporating material.

The vacuum chamber 12 is provided with two heating means 6a, 6b that can independently heat each of the first and second box bodies 2, 3. Each of the heating means 6a, 6b has the same mode, e.g., is provided so as to enclose the circumference of each of the first and second box bodies 2, 3 and is provided with a thermal insulating material of Mo make and having a reflecting surface on the inner side thereof, and an electric heater having a filament of Mo make. The first and second box bodies 2, 3 are heated at a reduced pressure by each of the heating means 6a, 6b and indirectly heat the processing chamber 20 and the evaporating chamber 30 through the box bodies 2, 3, whereby the inside of the processing chamber 20 and the evaporating chamber 30 can be heated substantially uniformly.

Then, by heating the processing chamber 20 with one of the heating means 6a, the object S to be processed is heated to a predetermined temperature and is held at the temperature. The evaporating chamber 30 is heated by the other of the heating means 6b to thereby evaporate the metal evaporating material V. The evaporated metal atoms are supplied to the surface of the object S to be processed that is disposed inside the processing chamber 20 to cause them to be adhered to thereby form a metallic film. Further, in case the object to be processed has a crystalline structure, at the same time as the adhesion to the surface of the object to be processed, the metal atoms can be diffused into the grain boundary phases.

When the metal evaporating material V is evaporated, because, e.g., the first box body 2 is of a construction (substantially hermetically sealed construction) to have mounted the lid part 22 on the upper surface of the box part 21, there is a possibility that the evaporated atoms partly flow out of the box body 2 through the clearance between the box part 21 and the lid part 22. However, since the insulating material constituting the heating means 3 so disposed as to enclose the circumference of the box body 2 is also made of a material that does not react with the metal evaporating material V, the vacuum chamber 12 is not contaminated inside thereof, and the recovery of the metal evaporating material becomes easy.

Further, the vacuum chamber 12 is provided with a gas introduction means (not illustrated) which makes it possible to introduce the rare gas such as Ar and the like. This gas introduction means performs the evacuating processing for a predetermined period of time and, after stopping the operation of each of the heating means 6a, 6b, Ar gas of, e.g., 10 kPa is introduced to thereby perform the role of stopping the evaporation of the metal evaporating material V inside the second box body 3.

After having stopped the evaporation of the metal evaporating material V, the vacuum chamber 12 is reduced in pressure through the evacuating means 11, thereby reducing the pressure of the processing chamber 20 and the evaporating chamber 30 to a pressure which is higher than that of the vacuum chamber 12 by half a digit. As a result, the processing chamber 20 can be reduced to a predetermined pressure after stopping the evaporation of the metal evaporating material V, without taking out each of the first and second box bodies 2, 3. In addition, since the first box body 2 is constituted by the box part 21 and the lid part 22, the construction of the box body 2 itself becomes also simpler and, when the lid part 22 is removed, the upper surface is left open so that the taking in and out of the box body 2 of the object S to be processed also becomes easy. The mechanism and the like to take the object S to be processed into, and out of, the box body 2 within the vacuum chamber 12 is not needed any more. Therefore, the vacuum vapor processing apparatus 1 itself can be simplified in construction. In addition, if plural sets of first and second box bodies are arranged to be capable of being housed, a large amount of objects S to be processed can simultaneously be handled, attaining high productivity. Further, a description has so far been made of an example in which heating means 3 is provided inside the vacuum chamber 12. However, any one will serve the purpose as long as the box body 2 can be heated to a predetermined temperature, and the heating means may be disposed outside the vacuum chamber 12.

In the example, a description has been made of an example in which the pan 51 is provided in the second box body 3 which constitutes the evaporating vessel 3 and lid body 52 serving the role of an adjusting plate is provided. But without being limited thereto, the metal evaporating material V may be disposed on the floor of the second box body 3. On the other hand, an arrangement may also be made such that an adjusting plate having a plurality of holes is provided in the communicating passage 4 to adjust the amount of supply of the evaporated metal atoms to the processing chamber 20.

Further, in the example, a description has been made of an example in which the communicating passage 4 is provided integrally with the second box body. But without being limited thereto, the evaporating vessel 3 may be constituted, in a similar manner as the above-described processing vessel 2, of a box part and a lid part so that the metal evaporating material V can be placed in position in a state in which the lid part is removed. Further, in this example, a description has been made of an arrangement in which the processing vessel 2 and the evaporating vessel 3 are disposed in the vertical positional relationship with each other. The arrangement inside the vacuum chamber 12 is not limited to the above; the evaporating vessel 2 may also be provided by fixing it to the vacuum chamber.

Now, with reference to FIGS. 1 through 3, a description will be made of the processing to improve the magnetizing and coercive force of a sintered magnet S in a vacuum vapor processing by using the above-described vacuum vapor processing apparatus 1. The Nd—Fe—B sintered magnet S is manufactured as follows by a known method. That is, Fe, B and Nd are mixed at a predetermined composition ratio to thereby obtain an alloy member having a thickness of 0.05 mm˜0.5 mm by the known strip casting. On the other hand, an alloy member having a thickness of about 5 mm may be manufactured by the known centrifugal casting method. A small amount of Cu, Zr, Dy, Tb, Al or Ga may be added thereto during the formulation. Then the manufactured alloy member is once ground by the known hydrogen grinding process and then pulverized by the jet-mill pulverizing process.

Then, after forming into a predetermined shape such as a rectangular parallelepiped or a column in a mold with magnetic orientation, it is sintered under predetermined conditions to thereby obtain the above-described sintered magnet. In each of the steps for manufacturing the sintered magnet S, the conditions may respectively be optimized so that the average grain diameter of the sintered magnet S falls in a range of 1 μm˜5 μm or 7 μm˜20 μm.

If the mean grain diameter is larger than 7 μm, since the spinning force of the grains during generation of the magnetic field is increased, the degree of orientation is improved and additionally the surface area of grain boundary is reduced, and it is possible to efficiently diffuse at least one of Dy and Tb and thus to obtain a permanent magnet M having a remarkably high coercive force. If the mean grain diameter is larger than 25 μm, the rate in the grain boundary of grains including different grain orientation in one grain is extremely increased and the degree of orientation is deteriorated and, as a result, the maximum energy product, remanent flux density and the coercive force are respectively reduced.

On the other hand, if the mean grain diameter is smaller than 5 μm, the rate of single domain grains is increased and, as a result, a permanent magnet having very high coercive force can be obtained. If the mean grain diameter is smaller than 1 μm, since the grain boundary becomes small and complicated, the time required for performing the diffusing process must be extremely extended and thus the productivity is poor. As a sintered magnet S, the smaller the amount of oxygen content, the larger the speed of diffusion of Dy and Tb into the grain boundary phases. Therefore, the oxygen content in the sintered magnet S itself may be below 3000 ppm, preferably below 2000 ppm, and most preferably below 1000 ppm.

Then, the sintered magnet S manufactured in the above-described method is placed on the bearing grid 21a of the box part 21, and the Dy which is the metal evaporating material V is placed in the pan 51 in the second box body 3. Then, the second box body 3 is placed in a predetermined position that is enclosed by the heating means 6b inside the vacuum chamber 12. And the first box part 2 having mounted the lid part 22 on the opened upper surface of the box part 21 is placed in a predetermined position that is enclosed by the heating means 6a inside the vacuum chamber 12 (as a result, the sintered magnet S and the metal evaporating material V are disposed apart from each other inside the vacuum chamber 12; see FIG. 1).

Then, the vacuum chamber 12 is evacuated to a predetermined pressure (e.g., 1×10⁻⁴ Pa) via the evacuating means 11 (the processing chamber 20 and the evaporating chamber 30 are evacuated to a pressure that is higher by half a digit). When the vacuum chamber 12 has reached a predetermined pressure, each of the heating means 6a, 6b is operated to heat the processing chamber 20 and the evaporating chamber 30. When the sintered magnet S inside the processing chamber 20 has been heated to a predetermined temperature and is held at the temperature and, on the other hand, the temperature inside the evaporating chamber 20 has reached a predetermined temperature at the reduced pressure, Dy in the pan 51 starts evaporation. When the Dy starts evaporation, since the sintered magnet S is placed apart from Dy, the melted Dy will not be directly adhered to the sintered magnet S whose surface Nd-rich phase is melted. The evaporated metal atoms of Dy are supplied to the inside of the processing chamber 20 through the communicating passage 4 and are supplied toward, and adhered to, the surface of the sintered magnet S that is at a predetermined temperature, either directly or from a plurality of directions by repeating collisions inside the processing chamber 20. The adhered Dy is diffused into the grain boundary phases of the sintered magnet S, thereby obtaining a permanent magnet M.

In this case, the heating means 6a is controlled to make the temperature of the processing chamber 20 and consequently the temperature of the sintered magnet S to be in the range of 800° C.˜1100° C. If the temperature in the processing chamber 20 (and consequently the heating temperature of the sintered magnet S) is below 800° C., the speed of diffusion of the Dy atoms adhered to the surface of the sintered magnet into the grain boundary phases becomes low. There is therefore a possibility that the Dy atoms cannot be spread homogeneously into the grain boundary phases of the sintered magnet before a thin film is formed on the surface of the sintered magnet S. On the other hand, at a temperature exceeding 1100° C., there is a possibility that Dy atoms are excessively diffused into the grain boundaries. If Dy is diffused into the grain boundaries, the magnetization within the grain boundaries may largely be lowered and, as a result, the maximum energy product and the remanent flux density are further lowered.

Further, the heating means 6b is controlled to make the temperature of the evaporating chamber 30 and consequently the temperature of the metal evaporating material to be in the range of 800° C.˜1200° C. (the vapor pressure of Dy will be about 1×10⁻³˜5 Pa). If the temperature of the metal evaporating material is below 800° C., there will not be attained a vapor pressure at which the metal atoms of Dy and Tb can be supplied to the surface of the sintered magnet S so as to diffuse Dy and Tb into the grain boundary phases for homogeneous penetration. On the other hand, at a temperature exceeding 1200° C., the vapor pressure of the metal evaporating material becomes so high that the evaporated Dy atoms are excessively supplied to the surface of the sintered magnet S and, as a result, there will be formed, on the surface of the sintered magnet, a thin film made of the metal evaporating material. In addition, the lid body 52 is mounted on the upper surface of the pan 51 to thereby reduce the amount of Dy atoms to the processing chamber 20.

This enables the amount of supply of Dy atoms to the sintered magnet S to be suppressed due to the reduction of the vapor pressure as well as the evaporation amount of Dy, and also enables the diffusion velocity to be accelerated due to heating of the sintered magnet S within a predetermined range of temperature while making the average grain diameter of the sintered magnet S to fall within a predetermined range. Accordingly, it is possible to efficiently and homogeneously diffuse and penetrate the Dy atoms adhered to the surface of the sintered magnet S into the grain boundary phases of the sintered magnet S before they deposit on the surface of the sintered magnet S and form the Dy layer (thin film) (see FIG. 3). As a result, it is possible to prevent the surface of permanent magnet M from being deteriorated and also to restrict the Dy to be excessively diffused into grain boundaries near the surface of the sintered magnet. As a result of having Dy-rich phase (the phase containing Dy in the range of 5˜80%) in the grain boundary phases and further as a result of Dy's diffusion only in a region near the surface of the grains, it is possible to effectively improve or recover the magnetizing properties and coercive force and thus to obtain a permanent magnet M superior in productivity without requiring any finishing work.

By the way, after having manufactured the above-described sintered magnet S, there are cases where it is worked into a desired shape by a wire cutting tool and the like. At that time, due to the above-described working, there will sometimes occur cracks to the grains which are the principal phase on the surface of the sintered magnet, resulting in a remarkable deterioration in the magnetic properties. On the other hand, when the above-described vacuum vapor processing is performed, due to the fact that Dy-rich phases are formed on the inside of the cracks of the grains near the surface, magnetizing properties and coercive force are recovered.

In addition, since Co was added to the conventional neodymium magnet because corrosion prevention measures must be taken. However, due to the fact that Dy-rich phase that has extremely higher corrosion resistivity and weather resistivity than Nd are present on the inside of the cracks in the grains near the surface and in the grain boundary phases, there can be obtained a permanent magnet that has extremely high corrosion resistivity and weather resitivity without using Co. In case the Dy that has been adhered to the surface of the sintered magnet is diffused, the metal atoms of Dy and Tb that have been adhered to the surface of the sintered magnet S can be diffused even more efficiently due to the fact that, in the grain boundaries of the sintered magnet S, there is no intermetallic compound containing Co.

Finally after having performed the above-described processing for a predetermined period of time (e.g., 4˜48 hours), the operation of the heating means 6a, 6b is stopped. Argon (Ar) gas of 10 KPa is then introduced into the processing chamber 20 and the evaporating chamber 30 through gas introducing means (not illustrated) to stop the evaporation of the metal evaporating material V. Subsequently, the temperature in the processing chamber 20 is once reduced to, e.g., 500° C. Subsequently the heating means 6a is operated once again and set the temperature in the processing chamber 20 to the range of 450° C.˜650° C. In order to further improve or recover the coercive force, heat treatment to remove the strain in the permanent magnet is performed. Finally, after rapidly cooling to substantially room temperature, the vacuum chamber 12 is vented, and each of the first and the second box bodies 2, 3 is taken out of the vacuum chamber 12.

In this example, a description has been made of an example of using Dy as the metal evaporating material V. It is possible to use Tb that is low in vapor pressure, in a heating temperature range (900° C.˜1000° C.) of the sintered magnet S that can accelerate the optimum diffusion velocity. Alternatively, an alloy of Dy and Tb may be used. In case the metal evaporating material V is Tb, the evaporating chamber 30 may be heated in the range of 900° C.˜1200° C. At a temperature below 900° C., the vapor pressure that can supply the Tb atoms to the surface of the sintered magnet S cannot be reached.

In the example a description has been made of an example of applying the vacuum vapor processing apparatus 1 in which magnetic properties of the Nd—Fe—B sintered magnet are improved. But without being limited to the example, the vacuum vapor processing apparatus 1 can be used in manufacturing, e.g., superhard material, hard material and ceramic material.

In other words, superhard material, hard material and ceramic material to be manufactured in powder metallurgy method are mainly made up of a principal phase and a boundary phase (binder phase) that becomes a liquid phase at the time of sintering. The liquid phase is in general prepared by grinding in a state in which the total quantity is mixed with the principal phase to thereby obtain raw meal, the raw meal is then molded in a known molding method, and is finally sintered. In case of manufacturing by using the above-described vacuum vapor processing apparatus 1, first, only the principal phase (in this case, liquid phase composition may partly be contained) is ground to prepare raw meal, then the raw meal is molded in a known molding method, and thereafter the liquid phase composition is supplied by the vacuum vapor processing apparatus before sintering, during sintering, or after sintering.

According to this arrangement, by subsequently supplying the liquid phase to the already molded principal phase, there can be created a peculiar grain phase composition because the time of reaction with the principal phase can be shortened, and demixing or segregation into the grain phase is possible at high concentration, and the like. As a result, it becomes possible to manufacture superhard material, hard material, and ceramic material that have high mechanical strength, particularly high toughness.

For example, SiC powder and C powder (carbon black) of an average particle size of 0.5 μm are mixed at a molar ratio of 10:1 to thereby obtain raw meal. Then, the raw meal is molded in a known method to thereby obtain a molded body (principal phase) of a predetermined shape. Then, this molded body is made to be an object S to be processed and the metal evaporating material V, which is selected to be Si, are contained in the first and the second box bodies 2, 3, respectively. Each of the box bodies 2, 3 is placed in a position which is enclosed by the heating means 6a, 6b inside the vacuum chamber 12.

Then, the vacuum chamber 12 is evacuated by the evacuating means 11 until the vacuum chamber 12 reaches a predetermined pressure (e.g., 1×10⁻⁵ Pa). Each of the heating means 6a, 6b is operated to heat the processing chamber 20 and the evaporating chamber 30 to a predetermined temperature (e.g., 1500° C.˜1600° C.). When the temperature in the evaporating chamber 30 has reached the predetermined temperature at reduced pressure, Si in the evaporating chamber 30 starts evaporation, and the processing chamber 20 is supplied with Si atoms. When this state is maintained for a predetermined period of time (e.g., 2 hours), the liquid phase which is Si is supplied at the same time as the sintering of the principal phase which is the molded body, whereby silicon carbide ceramic is manufactured.

The silicon carbide ceramic manufactured in the above-described method has a bending strength exceeding 1400 MPa and its fracture toughness is 4 MPa·m³. In this case, it can be seen that this product had a higher mechanical strength as compared with the one that was obtained by: mixing SiC powder and C powder (carbon black) of an average particle size of 0.5 μm at a molar ratio of 10:2 to thereby obtain raw meal; molding the raw meal in a known method; and then sintering it to thereby obtain the product (bending strength: 340 MPa, fracture toughness: 2.8 MPa·m³). It is to be noted that a mechanical strength equivalent to the above can also be obtained in case silicon carbide ceramic is obtained by: sintering a molded body under predetermined conditions (1600 ° C., 2 hours); and then supplying the composition of the liquid phase material which is Si by using the vacuum vapor processing apparatus 1.

### EXAMPLE 1

As a Nd—Fe—B sintered magnet, a member machined to a column shape (φ40×10 mm) having a composition of 30Nd-1B-0.1Cu-2Co-bal.Fe, O₂ content of the sintered magnet S itself of 500 ppm, and average grain diameter of 3 μm was used. In this example, the surface of the sintered magnet S was finished so as to have the surface roughness of 100 μm or less and then acid-cleaned with etchant and then washed with water.

Then, the vacuum vapor processing apparatus 1 was used and in the vacuum vapor processing method described above, Dy atoms were caused to be adhered to the surface of the sintered magnet S and were diffused into the grain boundary phases before thin film of Dy was formed on the surface of the sintered magnet S, whereby a permanent magnet M was obtained (vacuum vapor processing). In this case, the sintered magnet S was placed on the bearing grid 21a inside the processing chamber 20 and Dy of 99.9% degree of purity was used as the metal evaporating material, and a total amount of 10 g in bulk form was placed on the bottom surface of the processing chamber 20.

Then, the vacuum chamber was once reduced to 1×10⁻⁴ Pa (the pressure in the processing chamber was 5×10⁻³ Pa) by operating the evacuating means, and the heating temperature of the processing chamber 20 by the heating means 3 was set at 975° C. After the temperature in the processing chamber 20 has reached 975° C., the vacuum vapor processing was performed for 4 hours in that state.

### COMPARATIVE EXAMPLE 1

A film-forming process was performed on the sintered magnet S that is the same as the one used in the Example 1, by using a vapor deposition apparatus (VFR-200M/manufactured by ULVAC Machinery Co., Ltd.) of a conventional resistor heater type using a Mo board. In this Comparative Example 1, an electric current of 150 A was supplied to the Mo board and performed the film-forming process for 30 minutes after Dy of 4 g had been set on the Mo board and the vacuum chamber had been evacuated to 1×10⁻³ Pa.

FIG. 4 is a photograph showing a surface condition of the permanent magnet obtained by performing the processing described above and FIG. 4(a) is a photograph of the front side of sintered magnet S (before processing). It is found from this photograph that in the sintered magnet S of “before processing” although black portions such as voids of Nd-rich phase which is grain boundary phase or de-grain traces can be seen, the black portions disappear when the surface of the sintered magnet is covered by the Dy layer (thin film) as in the Comparative Example 1 (see FIG. 4(b)). In this case, the measured value of thickness of the Dy layer (thin film) was 20 μm. On the other hand, it is found in the Example 1 that black portions such as voids of Nd-rich phase or de-grain traces can be seen and thus are substantially the same as those of the surface of sintered magnet S of “before processing”. In addition it is found that Dy has been efficiently diffused into the grain boundary phases before formation of the Dy layer due to the change in weight (see FIG. 4(c)).

FIG. 5 is a table showing the magnetic properties of the permanent magnet M obtained in accordance with the conditions described above. Magnetic properties of the sintered magnet S “before processing” are shown in the table as a comparative example. According to this table it is found that the permanent magnet M of the Example 1 has the maximum energy product of 49.9 MGOe, the remanent flux density of 14.3 kG, and the coercive force of 23.1 kOe, and thus the coercive force (23.1 kOe) is remarkably improved as compared with that (11.3 kOe) of the sintered magnet S before the vacuum vapor processing.

### BRIEF DESCRIPTION OF THE DRAWINGS

FIG. 1 is a schematic view to explain the construction of a vacuum processing apparatus of this invention;

FIG. 2 is an enlarged perspective view of a pan;

FIG. 3 is a schematic explanatory view of a cross-section of a permanent magnet manufactured in accordance with this invention;

FIG. 4 is an enlarged surface photograph of a permanent magnet manufactured in accordance with this invention; and

FIG. 5 is a table showing the magnetic properties of a permanent magnet manufactured in accordance with this invention.

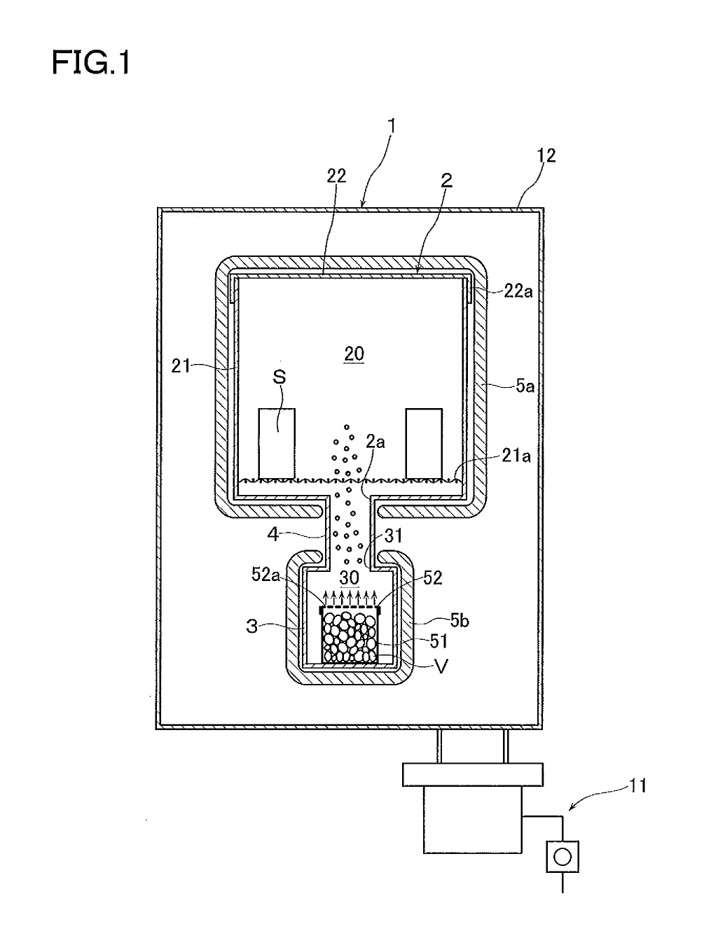

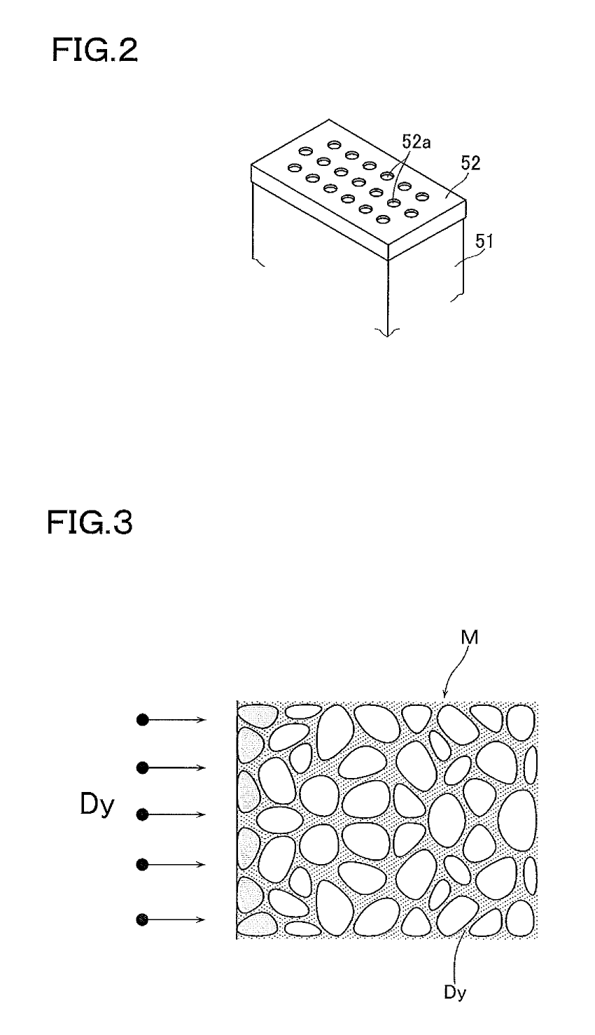

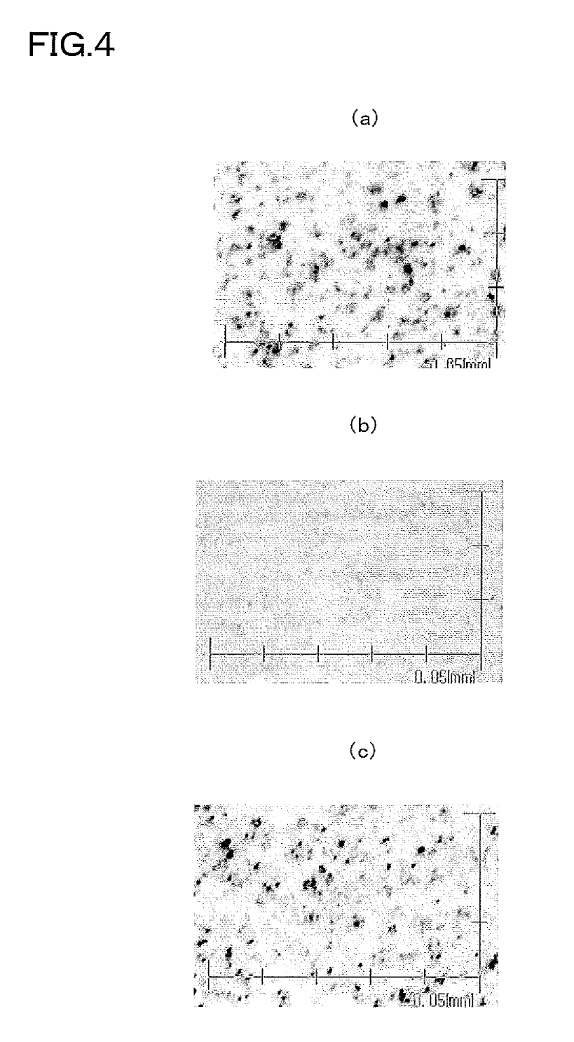

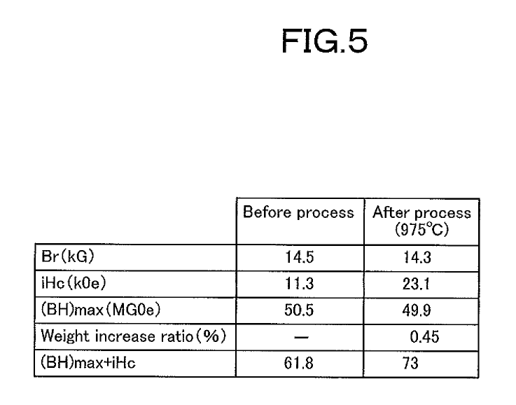

### DESCRIPTION OF REFERENCE NUMERALS

1 vacuum vapor processing apparatus
12 vacuum chamber
2 box body (processing vessel)
20 processing chamber
21 box part
22 lid part
3 box body (evaporating vessel)
4 communicating passage
5 heating means
61 pan evaporating vessel
62 adjusting board (lid body)
S object to be processed
V metal evaporating material

1. A vacuum vapor processing apparatus comprising:
a vacuum chamber capable of keeping inside thereof at a predetermined pressure;
a processing vessel and an evaporating vessel, both being disposed in the vacuum chamber at a distance from, and in communication with, each other; and
a heating means capable of heating the processing vessel and the evaporating vessel in a state in which an object to be processed is disposed in the processing vessel and in which metal evaporating material is disposed in the evaporating vessel,
wherein the processing vessel and the evaporating vessel are respectively heated by the heating means to thereby evaporate the metal evaporating material while raising the object to be processed to a predetermined temperature so that evaporated metal atoms are supplied to a surface of the object to be processed in the processing vessel.

2. The vacuum vapor processing apparatus according to claim 1, wherein the evaporating vessel is provided with a pan which is capable of disposing therein the metal evaporating material.

3. The vacuum vapor processing apparatus according to claim 1, wherein an adjusting plate that adjusts an amount of supply of the evaporated metal atoms to the processing vessel is mounted on an open upper surface of the pan or in a communicating passage between the processing vessel and the evaporating vessel.

4. The vacuum vapor processing apparatus according to claim 1, wherein the processing vessel is a first box body comprising a box part whose upper surface is open, and a lid part which is detachably mounted on the open upper surface of the box part, wherein the first box part can be taken into, or taken out of, the vacuum chamber, and wherein the inner space of the first box part is reduced to a predetermined pressure accompanied by pressure reduction in the vacuum chamber.

5. The vacuum vapor processing apparatus according to claim 1, further comprising a bearing grid which is capable of mounting thereon the object to be processed at a predetermined height from a bottom of the processing vessel, and wherein the bearing grid is made by arranging a plurality of wire rods.

6. The vacuum vapor processing apparatus according to claim 1, wherein the evaporating vessel is a second box body comprising a box part whose upper surface is open, and a lid part which is detachably mounted on the open upper surface of the box part, wherein the second box part can be taken into, or taken out of, the vacuum chamber, and wherein the inner space of the second box part is reduced to a predetermined pressure accompanied by pressure reduction in the vacuum chamber.

7. The vacuum vapor processing apparatus according to claim 1, wherein the processing vessel, the evaporating vessel, and the heating means: are made of a material that is free from reaction with the metal evaporating material; or have, on at least the surface thereof, a lining film made of a material that is free from reaction with the metal evaporating material.

8. The vacuum vapor processing apparatus according to claim 1, wherein the object to be processed is an iron-boron-rare earth sintered magnet, and wherein the metal evaporating material contains at least one of Dy and Tb.

9. The vacuum vapor processing apparatus according to claim 2, wherein an adjusting plate that adjusts an amount of supply of the evaporated metal atoms to the processing vessel is mounted on an open upper surface of the pan or in a communicating passage between the processing vessel and the evaporating vessel.

10. The vacuum vapor processing apparatus according to claim 2, wherein the processing vessel is a first box body comprising a box part whose upper surface is open, and a lid part which is detachably mounted on the open upper surface of the box part, wherein the first box part can be taken into, or taken out of, the vacuum chamber, and wherein the inner space of the first box part is reduced to a predetermined pressure accompanied by pressure reduction in the vacuum chamber.

11. The vacuum vapor processing apparatus according to claim 3, wherein the processing vessel is a first box body comprising a box part whose upper surface is open, and a lid part which is detachably mounted on the open upper surface of the box part, wherein the first box part can be taken into, or taken out of, the vacuum chamber, and wherein the inner space of the first box part is reduced to a predetermined pressure accompanied by pressure reduction in the vacuum chamber.

12. The vacuum vapor processing apparatus according to claim 2, further comprising a bearing grid which is capable of mounting thereon the object to be processed at a predetermined height from a bottom of the processing vessel, and wherein the bearing grid is made by arranging a plurality of wire rods.

13. The vacuum vapor processing apparatus according to claim 3, further comprising a bearing grid which is capable of mounting thereon the object to be processed at a predetermined height from a bottom of the processing vessel, and wherein the bearing grid is made by arranging a plurality of wire rods.

14. The vacuum vapor processing apparatus according to claim 2, wherein the evaporating vessel is a second box body comprising a box part whose upper surface is open, and a lid part which is detachably mounted on the open upper surface of the box part, wherein the second box part can be taken into, or taken out of, the vacuum chamber, and wherein the inner space of the second box part is reduced to a predetermined pressure accompanied by pressure reduction in the vacuum chamber.

15. The vacuum vapor processing apparatus according to claim 3, wherein the evaporating vessel is a second box body comprising a box part whose upper surface is open, and a lid part which is detachably mounted on the open upper surface of the box part, wherein the second box part can be taken into, or taken out of, the vacuum chamber, and wherein the inner space of the second box part is reduced to a predetermined pressure accompanied by pressure reduction in the vacuum chamber.

16. The vacuum vapor processing apparatus according to claim 2, wherein the processing vessel, the evaporating vessel, and the heating means: are made of a material that is free from reaction with the metal evaporating material; or have, on at least the surface thereof, a lining film made of a material that is free from reaction with the metal evaporating material.

17. The vacuum vapor processing apparatus according to claim 3, wherein the processing vessel, the evaporating vessel, and the heating means: are made of a material that is free from reaction with the metal evaporating material; or have, on at least the surface thereof, a lining film made of a material that is free from reaction with the metal evaporating material.

18. The vacuum vapor processing apparatus according to claim 2, wherein the object to be processed is an iron-boron-rare earth sintered magnet, and wherein the metal evaporating material contains at least one of Dy and Tb.

19. The vacuum vapor processing apparatus according to claim 3, wherein the object to be processed is an iron-boron-rare earth sintered magnet, and wherein the metal evaporating material contains at least one of Dy and Tb.
